(19) United States
(12) Patent Application Publication
(10) Pub. No.: US 2026/0011563 A1
(43) Pub. Date: Jan. 8, 2026

(54) THROUGH SUBSTRATE VIA AND FORMING METHOD THEREOF

(71) Applicant: Taiwan Semiconductor Manufacturing Company, Ltd., Hsinchu (TW)

(72) Inventors: Rui-Ke Wu, Nantou County (TW); Keng-Ying Liao, Tainan City (TW); Po-Zen Chen, Tainan City (TW); Chih Wei Sung, Kaohsiung (TW); Chien-Chung Chen, Kaohsiung City (TW); Hsien-Kai Tseng, New Taipei City (TW)

(73) Assignee: Taiwan Semiconductor Manufacturing Company, Ltd., Hsinchu (TW)

(21) Appl. No.: 18/764,036

(22) Filed: Jul. 3, 2024

(51) Int. Cl. H01L 21/3065; H01L 21/321; H01L 21/768

(52) U.S. Cl. CPC H01L 21/30655; H01L 21/32115; H01L 21/76831; H01L 21/76877; H01L 21/76898

(57) ABSTRACT

The present disclosure relates to a method, which includes forming a patterned mask layer having an opening disposed on a first surface of a substrate; performing a cyclic etching and deposition processes from the first surface to form a recess corresponding to the opening and a liner layer disposed thereon; performing a first removal process to remove the liner layer for exposing a portion of the substrate in the recess; and performing a trimming process to remove the portion of the substrate in the recess.

### BACKGROUND

The semiconductor industry has continually improved the processing capabilities and power consumption of integrated circuits (ICs) by shrinking the minimum feature size. However, in recent years, process limitations have made it difficult to continue shrinking the minimum feature size. The stacking of two-dimensional (2D) ICs into three-dimensional (3D) ICs has emerged as a potential approach to continue improving processing capabilities and power consumption of ICs.

More recent attempts have focused on through substrate vias. Generally, through substrate vias are formed by etching a vertical via through a substrate and filling the via with a conductive material, such as copper. The through substrate vias may be used to provide an electrical contact on a side of the substrate to a corresponding circuit, a circuit board, an interposer or another die on an opposing side of the substrate. In this manner, dies may be stacked while maintaining a smaller package size.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1M illustrate exemplary cross-sectional views of a method of manufacturing a through substrate via.

FIG. 2 illustrates an exemplary cross-sectional view of a semiconductor structure.

FIG. 3 illustrates an exemplary cross-sectional view of a semiconductor structure.

FIG. 4 illustrates an exemplary cross-sectional view of a semiconductor structure.

FIG. 5 illustrates an exemplary cross-sectional view of a semiconductor structure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

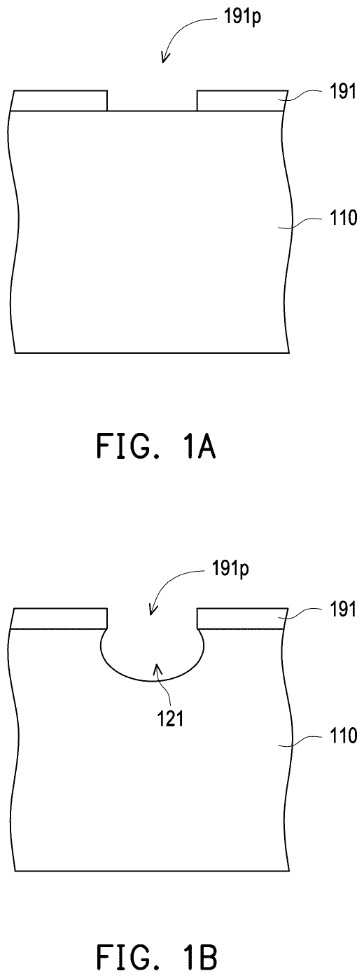

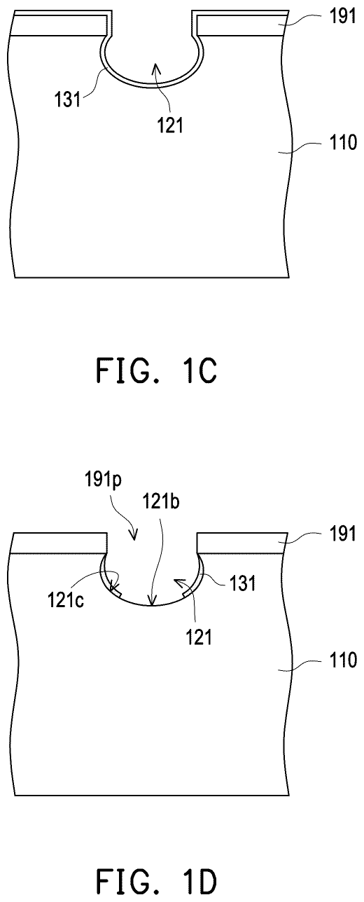

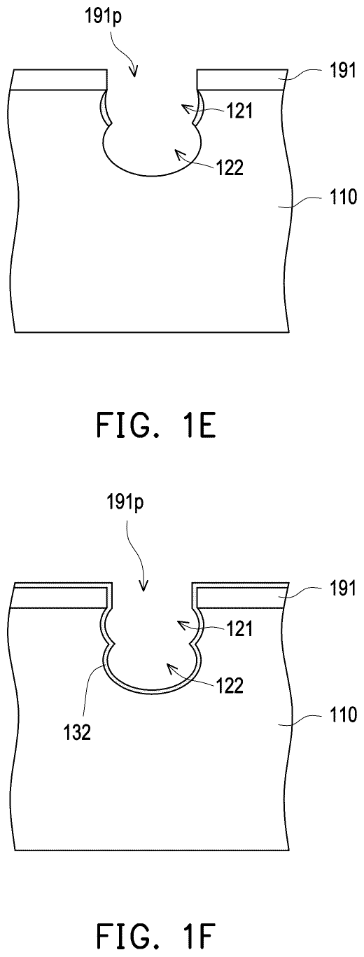

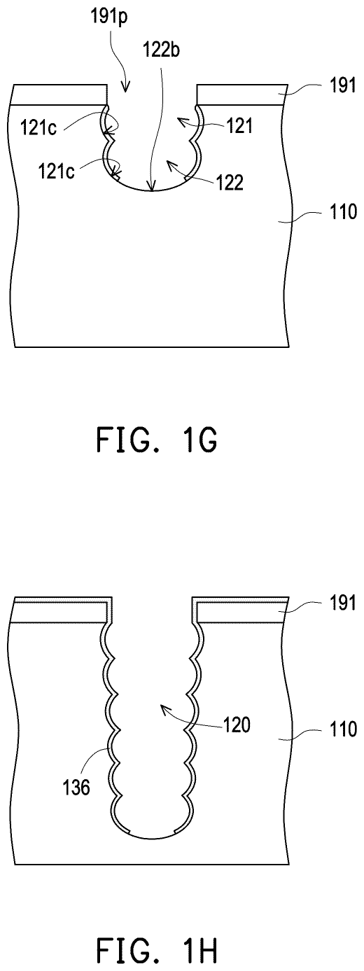

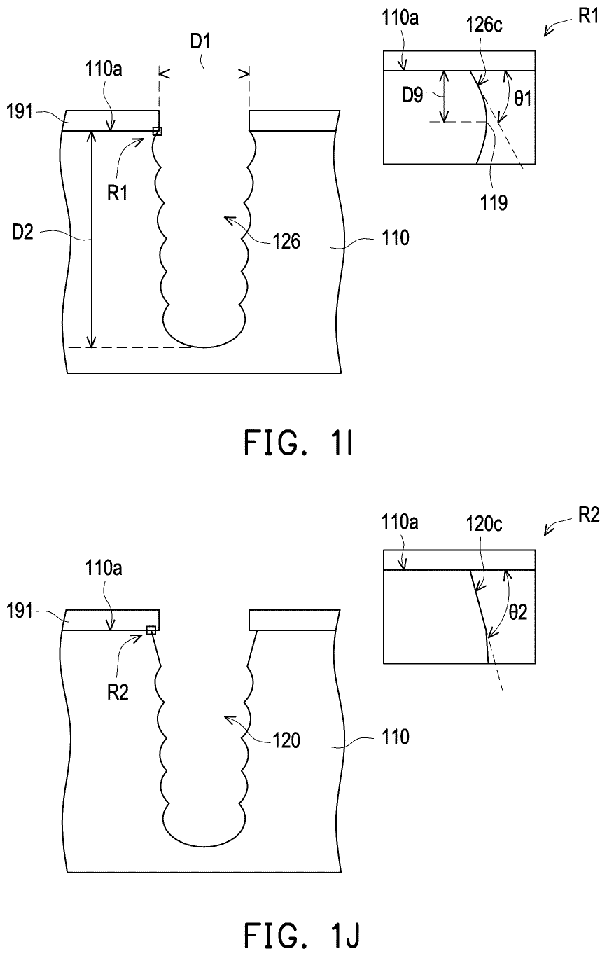

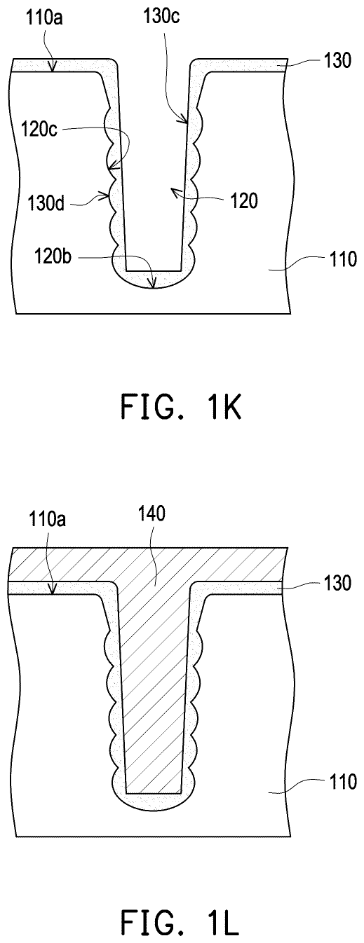

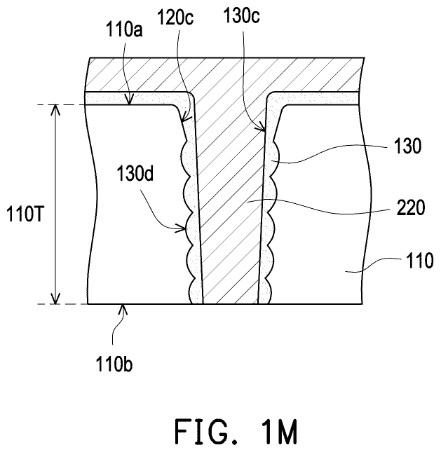

FIGS. 1A-1M illustrate exemplary cross-sectional views of a method of manufacturing a through substrate via. For example, FIGS. 1A-1M illustrate exemplary cross-sectional views of a method of manufacturing a through silicon via for an electronic component.

Referring to FIG. 1A, a portion of a substrate 110 with an overlying patterned mask layer 191 is provided.

The substrate 110 may be carried by a carrier (e.g., a grooving tape; not shown), but the disclosure is not limited thereto. In an embodiment, the substrate 110 includes a semiconductor substrate having an elementary semiconductor such as silicon, germanium and/or a compound semiconductor such as silicon germanium, silicon carbide, gallium arsenic, indium arsenide, gallium nitride or indium phosphide. For example, the semiconductor substrate is a silicon-on-insulator (SOI) substrate or a silicon substrate (e.g., a silicon wafer). In an embodiment, the semiconductor substrate takes the form of a planar substrate. In an embodiment, the semiconductor substrate is a bare substrate. For example, the semiconductor substrate is a silicon substrate without active device forming thereon or therein for being an interposer. In various embodiments, the semiconductor substrate includes a substrate with multiple fins, nanowires, or other forms known to people having ordinary skill in the art.

The patterned mask layer 191 includes one or more layers (e.g., a hard mask layer and/or a patterned photoresist layer) for defining a pattern and/or position of a through substrate via (as shown in a subsequently drawing).

The patterned mask layer 191 is patterned using, for example, photolithography techniques known in the art. For example, a hard mask material (e.g., silicon oxide, silicon nitride, silicon oxynitride, or a combination or stack thereabove) is formed by, for example, a thermal oxidation process, a deposition (e.g., a chemical vapor deposition (CVD)) process, or the like. Subsequently, a photoresist material is formed by, for example, a coating (e.g., a spin coating) process, or the like. A photolithography technique is performed by irradiating the aforementioned photoresist material in accordance with a pattern. Thereafter, the photoresist material is developed to remove a portion thereof. The remaining photoresist material protects the underlying material during subsequent processing steps, such as etching. The patterned mask layer 191 including the patterned photoresist layer and the patterned hard mask layer having a same or similar pattern is substantially formed.

In this case, an opening 191p of the patterned mask layer 191 is utilized for define a corresponding recess (which will become the through substrate via as discussed below).

Referring to FIG. 1A to FIG. 1B, a first recess 121 corresponding the opening 191p of the patterned mask layer 191 is formed by a first etching process.

In an embodiment, the first etching process includes a dry etch process. As a result of

using an isotropic dry etch process (as opposed to an anisotropic etch process), a recess (e.g., the same as or similar to the first recess 121) that extends laterally as well as vertically is formed. The isotropic etch process may create an undercut region under the patterned mask layer 191.

In an embodiment, the first etching process is performed by introducing a first etching gas that etches the substrate 110 until the desired depth of the first recess 121 is reached, at which point the first etching gas is stopped. For example, a first etching gas, such as SF₆, is introduced at a flow rate of about 50 sccm (Standard Cubic Centimeter per Minute) to about 200 sccm, at a pressure of about 10 mTorr to about 100 mTorr, at a power of plasma source of about 100 Watts to about 3000 Watts, and at a temperature of about −35° C. (degree Celsius) to about 100° C. for a time period between about 1 second to about 7 seconds to form a first recess 121 as illustrated in FIG. 1.

Referring to FIG. 1B to FIG. 1C, a liner layer 131 at least along a wall surface of the first recess 121 is formed by a deposition process. For example, a deposition gas is introduced at a flow rate of about 100 sccm to about 300 sccm, at a pressure of about 10 mTorr to about 50 mTorr, at a power of plasma source of about 1000 Watts to about 3500 Watts, and at a temperature of about 25° C. to about 100° C. for a time period between about 1 second to about 10 seconds. The deposition gas includes fluorocarbon gas (e.g., hexafluoropropene (C₃F₆) or octafluorocyclobutane (cyclic-C₄F₈)), a fluorinated hydrocarbon gas (e.g., trifluoromethane (CHF₃)), or a mixture thereof. A corresponding bonding of the fluorocarbon or fluorinated hydrocarbon molecule is broken/opened with plasma for being radicals. Fluorocarbon polymers are generated when the radicals react with each other. The liner layer 131 is form when the fluorocarbon polymers are disposed on the surface. In an embodiment, the liner layer 131 is further formed on an outer surface of the patterned mask, but the disclosure is not limited thereto.

Referring to FIG. 1C to FIG. 1D, a portion of the liner layer 131 is removed by a second etching process.

In an embodiment, the second etching process includes a dry etch process. As a result of using an anisotropic dry etch process, a portion of the liner layer 131 disposed on the bottom surface 121b of the first recess 121 substantially vertically overlap to the opening 191p of the patterned mask layer 191 is removed to expose a portion of the bottom surface 121b of the first recess 121 substantially, but may still be slightly remained. Another portion of the liner layer 131 disposed on the side surface 121c of the first recess 121 is substantially remained, but may still be slightly etched.

The second etching process may be performed by introducing a second etching gas that etches the liner layer 131. Process parameters of the second etching process may be similar to process parameters of the aforementioned first etching process. In an embodiment, not only the second etching gas (e.g., SF₆), a bias gas (e.g., O₂) is further introduced. The bias gas may improve the anisotropy of second etching gas. If necessary, but not limited, a dilution or carrier gas (e.g., Ar) is further introduced.

Referring to FIG. 1D to FIG. 1E, after a portion of the liner layer 131 being removed to expose a portion of the bottom surface of the recess, an etching process the same as or similar to the aforementioned first etching process may be performed to further form a corresponding recess. For example, as shown in FIG. 1E, the etching process is performed to etch the substrate 110 until the desired depth of the second recess 122 under the first recess 121 is reached.

In an embodiment, the second etching process (e.g., the steps as shown in FIGS. 1C to FIG. 1D) and the further etching process thereafter (e.g., the steps as shown in FIGS. 1D to FIG. 1E) is a non-stopped or continuous etching process. For example, the power of high frequency radiation is applied continuously, and the type of etching gas is switched accordingly to perform the corresponding non-stopped or continuous etching process.

Referring to FIG. 1E to FIG. 1F, a liner layer 132 at least along a wall surface of the recess (e.g., including the first recess 121 and the second recess 122) is formed by a deposition process the same as or similar to the aforementioned deposition process. The liner layer 132 may include the remained portion of the liner layer 131 disposed on the side surface 121c of the first recess 121.

Referring to FIG. 1F to FIG. 1G, a portion of the liner layer 132 is removed by an etching process the same as or similar to the aforementioned second etching process. As such, a portion of the liner layer 132 disposed on the bottom surface 122b of the recess substantially vertically overlap to the opening 191p of the patterned mask layer 191 is removed to expose a portion of the bottom surface 122b of the recess 121 substantially, but may still be slightly remained. Another portion of the liner layer 132 disposed on the side surface 121c, 122c is substantially remained, but may still be slightly etched.

Processes as shown in FIG. 1E to FIG. 1G may be performed one or more times (e.g., 3˜1000 cycles), and the process as shown in FIG. 1E is further performed, to form a structure having a recess 126 as shown in FIG. 1H. In an embodiment, the aforementioned etching process for forming the recess 126 may be referred as a deep reactive ion etching (DRIE) process. The DRIE process for forming high aspect ratio microstructures onto semiconductor material (e.g., Si) is one of the key processes for the manufacturing of advanced electronic devices, such as in the MEMS field and/or through silicon via (TSV) applications.

Referring to FIG. 1H to FIG. 1I, after forming the recess 126 to the desired depth, the liner layer 136 is removed by an appropriate etching process, such as an etching process similar to the second process but performed for a longer time.

Referring to FIG. 1I to FIG. 1J, after removing the liner layer 136, a trimming process is performed to modify the profile of the recess. In an embodiment, after removing the liner layer 136, there is substantially no significant difference (e.g., <1%) in the depth of the recess before and after performing the aforementioned trimming process.

A trimming gas is introduced for performing the trimming process. The trimming gas is a mixture gas including a first gas and a second gas. The first gas may be the same as or similar to the aforementioned first etching gas, such as SF₆. The second gas may be the same as or similar to the aforementioned deposition gas, such as fluorocarbon gas (e.g., hexafluoropropene (C₃F₆) or octafluorocyclobutane (cyclic-C₄F₈)), a fluorinated hydrocarbon gas (e.g., trifluoromethane (CHF₃)), or a mixture thereof. Moreover, process parameters of the trimming process may be similar to process parameters of the aforementioned etching process or deposition process, for example, at a flow rate of about 50 sccm to about 300 sccm, at a pressure of about 10 mTorr to about 100 mTorr, at a power of plasma source of about 100 Watts to about 3000 Watts, and at a temperature of about 25° C. to about 100° C. for a time period between about 1 second to about 10seconds. In other words, the trimming process may be performed by an apparatus the same as for performing the aforementioned etching and/or deposition processes. For example, the trimming process and the aforementioned etching and/or deposition processes may be performed in a same chamber. As such, the efficiency of the equipment may be improved, and/or the interference or influence between different process reagents may be reduced.

For more clearly, an enlarged view (e.g., having an actual magnification of approximately 2,000,000 to 5,000,000 times) of the region R1 is shown in the upper right portion of FIG. 1I, and an enlarged view (e.g., having an actual magnification of approximately 2,000,000 to 5,000,000 times) of the region R2 is shown in the upper right portion of FIG. 1J.

Referring to FIG. 1I to FIG. 1J continuously, by performing the trimming process, a lateral undercut protrusion 119 may be reduced, and/or an included angle between the top surface 110a and a portion of the wall surface connecting to the top surface 110a may be closer to 90 degrees (e.g., from the included angle as shown in FIG. 1I to the included angle as shown in FIG. 1J). For example, as shown in FIG. 1I, on a cross-sectional view, before performing the aforementioned trimming process, a lateral undercut protrusion 119 (may be referred as “ring neck” or “necking”) closed to the top surface 110a (e.g., a vertical distance D9 is less than or approximately equal to 1 micrometer (μm)) could be found, and/or an included angle between the top surface 110a (including a virtual surface extending parallel therefrom) and a portion of the wall surface 126c connecting thereto could be less than 65 degrees (e.g., approximately 60 degrees). For example, as shown in FIG. 1J, on a cross-sectional view, after performing the aforementioned trimming process, an included angle between the top surface 110a (including a virtual surface extending parallel therefrom) and a portion of the wall surface 120c connecting thereto could be larger than or approximately equal to 65 degrees, or further larger than or approximately equal to 70 degrees (e.g., approximately 75 degrees). As such, in a subsequent process, a silicon-containing material may be adapted for covering or coating on the top surface 110a and the wall surface to form a corresponding layer. In addition, the aforementioned trimming process will not have a significant impact on the opening size D1 of the recess 120.

Referring to FIGS. 1I and 1J, at the level of the top surface, the opening size D1 of the recess 120 (may be referred as “critical dimension (CD)”) could be less than or equal to approximately 20 μm, or further in the range of approximately 5 μm to approximately 20 μm, or furthermore in the range of approximately 10 μm to approximately 15 μm. In a direction perpendicular to the top surface 110a, the depth D2 of the recess 120 could be in the range of approximately 0.5 μm to approximately 150 μm, or further in the range of approximately 0.5 μm to approximately 120 μm. In an embodiment, an aspect ratio (e.g., D2:D1) of the recess 120 is in the range of approximately 4:1 to approximately 30:1, or further in the range of approximately 6:1 to approximately 12:1. It is worth noting that only one recess 120 is shown in FIG. 1J, but the number and/or pattern of the recess 120 on the substrate 110 is not limited in the disclosure.

After the aforementioned trimming process, the patterned mask layer 191 may be removed by a removal process.

Referring to FIG. 1J to FIG. 1K, an insulating layer 130 is formed on the top surface 110a and further extends into the recess 120 to cover the wall surface 120c and bottom surface 120b thereof.

In an embodiment, the insulating layer 130 includes an insulating material, such as silicon oxide, silicon nitride, silicon oxynitride or the like, and may be formed by a suitable deposition process, such as a chemical vapor deposition (CVD) process, a physical vapor deposition (PVD) process, an atomic layer deposition (ALD) process, or the like. In an embodiment, the insulating layer 130 includes a silicon oxide layer formed by using tetraethyl orthosilicate (TEOS) as a raw material, and the forming method thereof is, for instance, low-pressure chemical vapor deposition (LPCVD). An insulating layer formed of TEOS material may be different from another insulating layer formed of other material in characteristics such as tensile stress, compressive stress, and/or resistance. In an embodiment, the insulating layer 130 is further referred as an insulating barrier layer.

In an embodiment, the wall surface 120c is completely filled by the insulating layer 130, creating a flatter surface for the following conductive material deposition. For example, the insulating layer 130 has a scallop-like sidewall 130d facing the substrate 110 and a substantially smooth sidewall 130c facing away the substrate 110 and/or facing the subsequently formed conductive layer. That is, with the insulating layer 130, a scallop-like surface (e.g., the scallop-like wall surface 120c) formed by the aforementioned etching process could be smoothly filled-in creating a quite flat surface (e.g., the surface of the sidewall 130c), which may improve subsequent film deposition (e.g., the deposition of a subsequent conductive layer 140), and/or may reduce the problem of discontinuous layer and/or film peeling caused by wall scalloping.

Referring to FIG. 1K to FIG. 1L, a conductive layer 140 is formed on the top surface 110a and further extends into the recess 120, and the insulating layer 130 is disposed between the conductive layer 140 and the substrate 110.

The conductive layer 140 may include a first conductive layer and a second conductive layer disposed thereon. A thickness of the first conductive layer is usually thinner than a thickness of the second conductive layer. The first conductive layer may include a conductive barrier layer, for example, a metal layer or a metal-containing layer doped with an impurity (e.g., boron) such as tantalum, tantalum nitride, titanium, titanium nitride, titanium zirconium, titanium zirconium nitride, tungsten, tungsten nitride, cobalt boron, cobalt tungsten, an alloy, combinations thereof, or the like. The first conductive layer may include a conductive seed layer, for example, a metal layer such as copper, tungsten, aluminum, silver, combinations thereof, or the like. The first conductive layer may be formed, for example, by physical vapor deposition (PVD), atomic layer deposition (ALD), spin-on deposition, or other suitable methods. The first conductive may have a thickness between about 50 Å (angstrom) and about 50,000 Å. The second conductive layer may include a metal layer such as copper, an alloy, combinations thereof. The first conductive layer may be formed, for example, by an electro-deposition process is utilized to fill the recess, although other suitable methods, such as electroless deposition, plating, or CVD, may also be used. A polishing (e.g., chemical mechanical polishing (CMP)) process may be performed on a portion of the conductive layer located outside of the recess 120.

In an embodiment, a patterning process is performed on a portion of the conductive layer 140 located outside of the recess 120 for forming a corresponding circuit layer, but the disclosure is not limited thereto. In an embodiment, one or more patterned insulating layer and/or one or more further circuit layers are formed on the aforementioned circuit layer for forming a corresponding circuit structure, but the disclosure is not limited thereto. In an embodiment, an electronic device (e.g., a chip) is configured on the substrate 110 and electrically connected to the aforementioned circuit layer, but the disclosure is not limited thereto.

Referring to FIG. 1L to FIG. 1M, a portion of the substrate 110 is removed from the back side 110b thereof by an appropriate removal process (e.g., a polishing process, a grinding process, or an etching process) for forming a hole formed from the recess 120 and penetrating through the substrate 110. The back side 110b of the substrate 110 is thinned until the conductive layer 140 is exposed. Additionally, a portion of the conductive layer 140 and a portion of the insulating layer 130 corresponding the bottom surface 120b of the recess 120 are removed during the aforementioned removal process. A portion of the conductive layer 140 filling in the hole is referred as a through substrate via 220.

In an embodiment, there is substantially no significant difference (e.g., <1%) in the depth of the recess before performing aforementioned removal process and in the depth of the hole after performing aforementioned removal process.

In an embodiment, the remaining thickness 110T of the thinned substrate 110 is in a range from about 10 μm to about 200 μm. An aspect ratio of the through substrate via 220 is in the range of approximately 4:1 to approximately 30:1, or further in the range of approximately 6:1 to approximately 12:1. The insulating layer 130 is disposed between the through substrate via 220 and the substrate 110. That is, the through substrate via 220 may be annularly wrapped by the insulating layer 130. The insulating layer 130 has a scallop-like sidewall 130d facing the substrate 110 and a substantially smooth sidewall 130c facing away the substrate 110 and/or facing the through substrate via 220. That is, a surface roughness of the sidewall 130d is larger than a surface roughness of the sidewall 130c. On a cross-sectional view (e.g., the view as shown in FIG. 1M or a similar drawing thereof), considering a profile of the substrate 110, an included angle (e.g., the angle as shown in FIG. 1J) between the top surface 110a (including a virtual surface extending parallel therefrom) and a portion of the wall surface 120c connecting thereto could be larger than or approximately equal to 65 degrees, or further larger than or approximately equal to 70 degrees (e.g., approximately 75 degrees).

After the above steps, the method of forming the through substrate via of the present embodiment may be roughly completed. In an embodiment, if the substrate 110 include a silicon substrate (e.g., a silicon wafer, a silicon chip, or a silicon interposer), the through substrate via is referred as a through silicon via. For example, at least one of the through substrate vias (TSVs) 220 as described below.

In an embodiment, other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

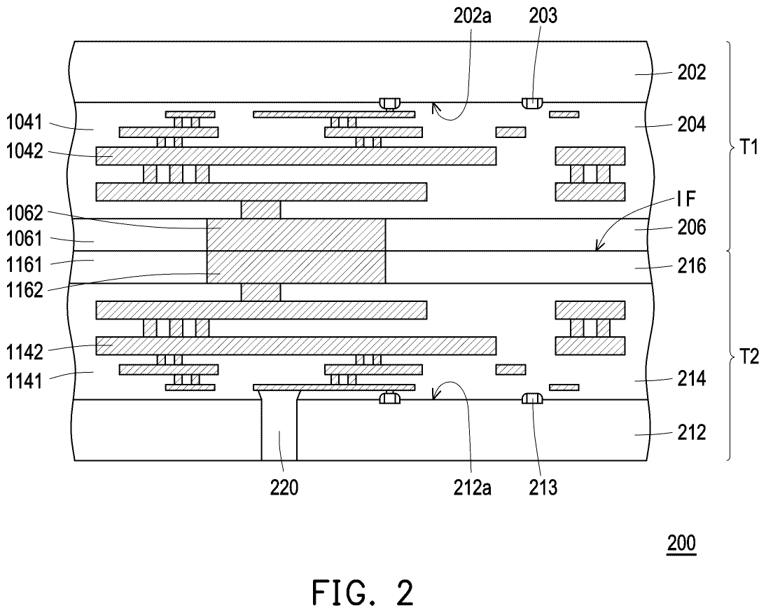

FIG. 2-FIG. 5 are schematic cross-sectional views showing various semiconductor

structures having a through substrate via according to some embodiments. The TSV described herein may be or may be a part of an Integrated-Fan-Out (InFO) package, a Chip-On-Wafer-On-Substrate package, a Chip-On-Wafer (CoW) package, a Wafer-On-Wafer (WoW) package, a system on a chip device, a system on integrated circuit devices, etc. The following embodiments are merely examples, and the TSV is not intended to be limited to any particular application type of semiconductor structure. Unless specified otherwise, the materials and the formation methods of the components in these embodiments are essentially the same as the like components, which are denoted by like reference numerals in the embodiments shown in FIG. 2-FIG. 5. The details regarding the materials of the components may thus be found in the discussion of the embodiments shown in FIG. 2-FIG. 5.

Referring to FIG. 2, a semiconductor structure 200 including the TSV 220 is provided. The semiconductor structure 200 may be or may include a plurality of dies stacked upon one another, and each die may be viewed as a tier of the semiconductor structure 200. For example, the semiconductor structure 200 includes a first tier T1 and a second tier T2 bonded to and electrically connecting the first tier T1. Although the structure below the second tier T2 is not shown, it should be understood that the structure below the second tier T2 may be similar to the second tier T2 to form a die stack. Other applications may be possible. The respective tier of the semiconductor structure 200 may be a logic die (e.g., central processing unit (CPU), graphics processing unit (GPU), system-on-a-chip (SoC), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. The tiers of the semiconductor structure 200 may perform the same function or different functions.

The first tier T1 may include a first semiconductor substrate 202, a first interconnect

structure 204 underlying the first semiconductor substrate 202, a first bonding structure 206 underlying the first interconnect structure 204. The second tier T2 may include a second semiconductor substrate 212, a second interconnect structure 214 overlying the second semiconductor substrate 212, the TSV 220 penetrating through the second semiconductor substrate 212 and extending into the second interconnect structure 214, and a second bonding structure 216 overlying the second interconnect structure 214. For example, the first bonding structure 206 is stacked upon and bonded to the second bonding structure 216. The first semiconductor substrate 202 and the second semiconductor substrate 212 are similar to the semiconductor substrate 212 described in the preceding paragraphs. The semiconductor devices (203 and 213) may be formed on the front surface (202a and 212a) of the first semiconductor substrate 202 and the second semiconductor substrate 212, respectively. The respective semiconductor device (203 and 213) may include the FEOL features such as transistors, diodes, capacitors, resistors, inductors, and/or the like.

The second interconnect structure 214 may include the dielectric layer 1141 and conductive pattern layers 1142 embedded in the dielectric layer 1141. The dielectric layer 1141 may include an interlayer delietric (ILD) formed over the front surface 212a of the semiconductor substrate 212 to cover the semiconductor devices 213. The ILD may include one or more dielectric layers formed of materials such as phosphosilicate glass (PSG), borosilicate glass (BSG), boron-doped phosphosilicate Glass (BPSG), undoped silicate glass (USG), the like, or combinations thereof. The dielectric layer 1141 may include IMD formed on the ILD and providing isolation for the conductive pattern layers 1142. Examples of the IMD include tetraethylorthosilicate (TEOS) oxide, un-doped silicon glass, or doped silicon oxide (e.g., BPSG, PSG, BSG, etc.) and/or other suitable insulating materials. In some embodiments, the TSV 220 extends into the ILD or may extend through the ILD. In some other embodiments, the TSV 220 passes through the ILD and further extends into the IMD. The first interconnect structure 204, similar to the second interconnect structure 214, may include the dielectric layer 1041 and the conductive pattern layers 1042 embedded in the dielectric layer 1041, and the conductive pattern layers 1042 may be electrically coupled to the semiconductor devices 203.

The TSV 220 may extend into the dielectric layers 1141 to be in physical and electrical contact with any level of the conductive pattern layers 1142, and the TSV 220 may be electrically coupled to the semiconductor devices 213 through the conductive pattern layers 1142 of the second interconnect structure 214. In some embodiments, the TSV 220 may extend beyond the rear surface 212b of the semiconductor substrate 212, and an isolating layer 1122 may be formed on the rear surface 212b to laterally cover the portion of the TSV 220 that is protruded from the rear surface 212b. The isolating layer 1122 may separate the second semiconductor substrate 212 from the underlying layers (e.g., metallic layers; not shown). The material of the isolating layer 1122 may be or may include a nitride, an oxide, an oxynitride, carbide, a polymer, and/or the like.

The first bonding structure 206 may include a bonding dielectric layer 1061 and a bonding conductor 1062 embedded in the bonding dielectric layer 1061, where the bonding dielectric layer 1061 underlies the dielectric layer 1041 and the bonding conductor 1062 is electrically coupled to the conductive pattern layers 1042. The second bonding structure 216, similar to the first bonding structure 206, may include a bonding dielectric layer 1161 and a bonding conductor 1162 embedded in the bonding dielectric layer 1161, where the bonding dielectric layer 1161 overlies the dielectric layer 1141 and the bonding conductor 1162 is electrically coupled to the conductive pattern layers 1142. In some embodiments, the bonding dielectric layer 1061 is physically bonded to the bonding dielectric layer 1161, and the bonding conductor 1062 is physically bonded to the bonding conductor 1162 to provide vertical connection between the first tier T1 and the second tier T2. For example, dielectric-to-dielectric bonds and metal-to-metal bonds are formed at the interface IF between the first tier Tl and the second tier T2, and the interface IF may be substantially flat.

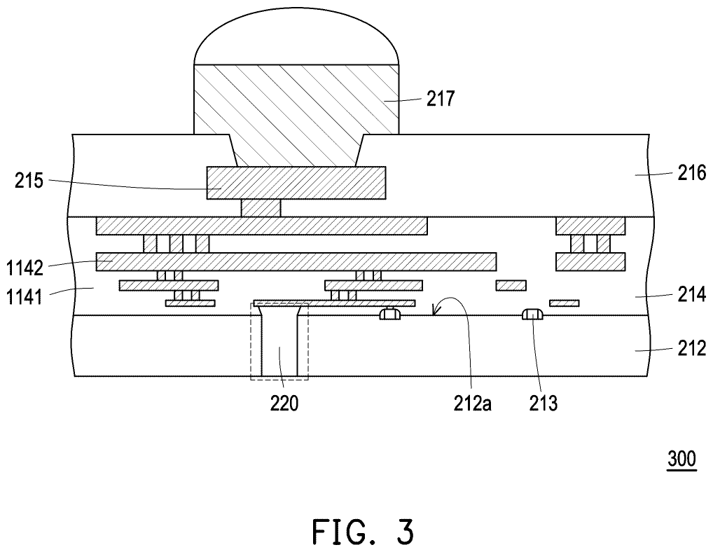

Referring to FIG. 3, a semiconductor structure 300 including the TSV 220 is provided. The semiconductor structure 300 includes the semiconductor substrate 212, the interconnect structure 214 overlying the semiconductor substrate 212, the TSV 220 penetrating through the semiconductor substrate 212 and extending into the dielectric layer 1141 of the interconnect structure 214. The TSV 220, similar to the TSV described in FIG. 2, may provide electrical coupling between one or more layers of conductive material within the semiconductor structure 300. The semiconductor structure 300 may include a contact pad 215 formed on the interconnect structure 214 and electrically coupled to the conductive pattern layers 1142, a passivation layer 216 formed on the dielectric layer 1141 and partially covering the contact pad 215, and a conductive terminal 217 formed on the contact pad 215 and electrically coupled to the semiconductor devices 213 through the contact pad 215 and the conductive pattern layers 1142. The contact pad 215 may be aluminum pad, although other suitable conductive materials (e.g., copper) may be used to for the contact pad 215. In some embodiments, the passivation layer 216 includes one or more layers of silicon oxide, silicon nitride, silicon oxynitride, the like, or a combination thereof. The openings may extend through the passivation layer 216 to the contact pad 215.

The conductive terminal 217 may be formed in the opening of the passivation layer 216 and land on the contact pad 215. In some embodiments, the conductive terminal 217 includes a metal pillar with a metal cap layer, which may be a solder cap, over the metal pillar. For example, the conductive terminal 217 may be or may include micro-bumps, controlled collapse chip connection (C4) bumps, metal pillars, solder balls, ball grid array (BGA) connectors, electroless nickel-electroless palladium-immersion gold (ENEPIG) formed bumps, or the like. The conductive terminal 217 may include a conductive material such as solder, copper, aluminum, gold, nickel, silver, palladium, tin, the like, or a combination thereof. The conductive terminal 217 may include bump shapes and/or may have substantially vertical sidewalls. It is noted that the shape of the conductive terminal 217 shown in FIG. 3 is provided for illustrative purposes, the conductive terminals 270 may have various cross section depending on the design requirements.

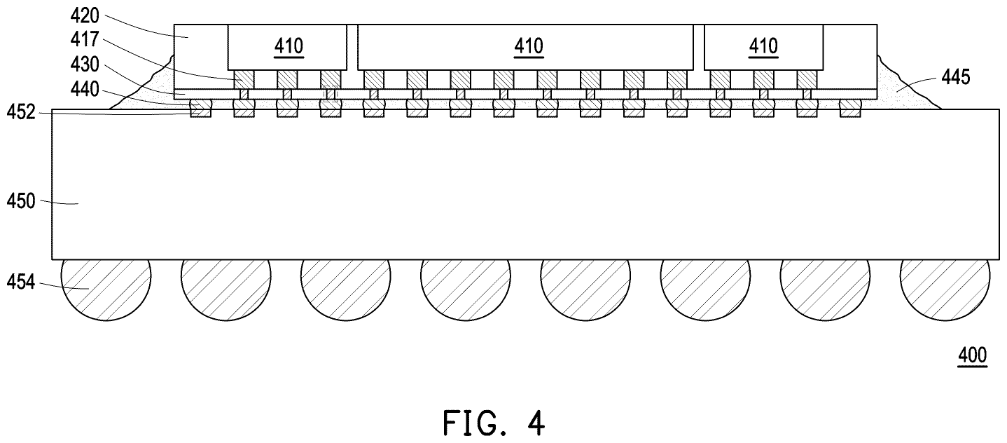

Referring to FIG. 4 and with reference to FIGS. 2-3, a semiconductor structure 400 including the TSV 220 is provided. In some embodiments, the semiconductor structure 400 is referred to as a semiconductor package. For example, the semiconductor structure 400 includes integrated circuit (IC) dies 410, an insulating encapsulation 420 laterally covering the IC dies 410, an interposer 430 disposed below the IC dies 410 and the insulating encapsulation 420, and a package substrate 450 disposed below the interposer 430 and electrically coupled to the IC dies 410 through the interposer 430. The interposer 430 may have allowed for a three-dimensional (3D) package that includes multiple IC dies 410 and also provide electrical routing between the one or more IC dies 410 and the package substrate 450.

In some embodiments, one or more IC dies 410 may include the die stack as shown in FIG. 2 or include the structure shown in FIG. 3. For example, the die connectors 417 of the IC dies 410 are similar to the conductive terminal 217 shown in FIG. 3. The insulating encapsulation 420 may be formed of a molding compound, epoxy, or the like, and may be applied by compression molding, transfer molding, or the like. For example, the die connectors 417 of the respective IC die 410 are accessibly exposed by the insulating encapsulation 420 for electrically connecting the interposer 430. In some embodiments, the interposer 430 includes the semiconductor substrate 212, the interconnect structure 214 formed on the semiconductor substrate 212, and the TSV 220 penetrating through the semiconductor substrate 212 and extending into the interconnect structure 214. The semiconductor substrate 212 of the interposer 430 may be free of semiconductor devices. In some embodiments, the die connectors 417 of the IC dies 410 are electrically coupled to the TSV 220 through the interconnect structure 214.

In some embodiments, the conductive joints 440 are physically and electrically connected to the interposer 430 and the conductive pads 452 of the package substrate 450. For example, the conductive joints 440 are solder joints. Although the conductive joints 440 may include other suitable conductive material(s). In some embodiments, an underfill layer 445 is formed between the interposer 430 and the package substrate 450 to laterally cover the conductive joints 440 for protection. The underfill layer 445 may extend to cover the sidewall of the interposer 430 and may further extend to cover the sidewall of the insulating encapsulation 420. In some embodiments, the package substrate 450 includes external terminals 454 for further electrical connection, where the external terminals 454 and the conductive pads 452 are formed at two opposing sides of the package substrate 450. For example, the external terminals 454 are connected to another package component such as a printed circuit board (PCB), a printed wiring board, additional package substrate, and/or other carrier that is capable of carrying integrated circuits. It should be noted that other packaging techniques may be used to form the semiconductor structure, which are not limited in the disclosure. The semiconductor structure described herein may be part of an electronic system for such as computers (e.g., high-performance computer), computational devices used in conjunction with an artificial intelligence system, wireless communication devices, computer-related peripherals, entertainment devices, etc. It should be noted that other electronic applications are also possible.

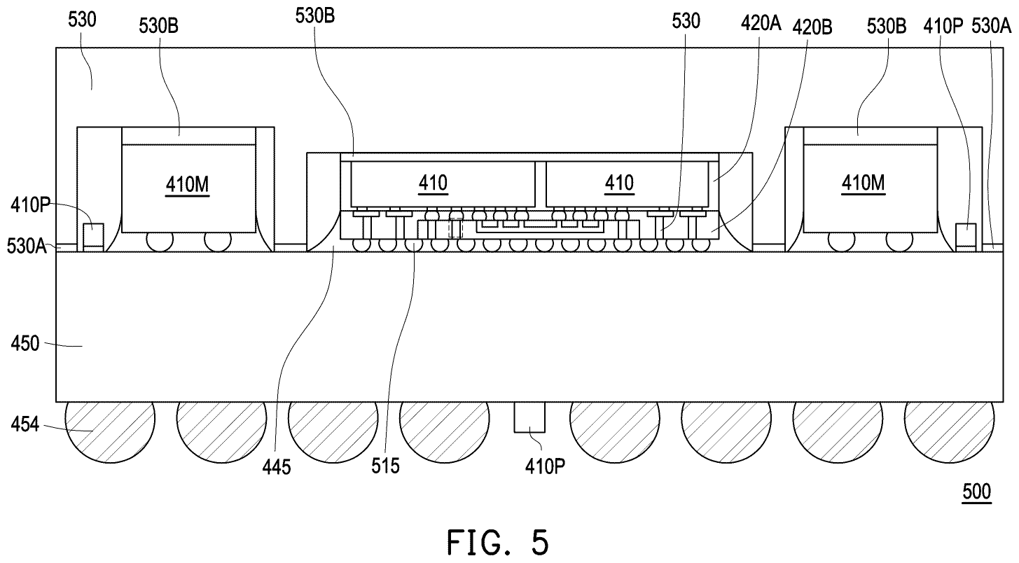

Referring to FIG. 5, a semiconductor structure 500 including the TSV 220 is provided. In some embodiments, more than one IC die 410 may be encapsulated by a first insulating encapsulation 420A, and a bridge die 510 underlying the IC dies 410 and the insulating encapsulation 420 may be electrically coupled to the IC dies 410. For example, the adjacent IC dies 410 are in electrical communication with each other through the bridge die 510. The bridge die 510 may be covered by a second insulating encapsulation 420B. The first insulating encapsulation 420A and/or the second insulating encapsulation 420B may be similar to the insulating encapsulation 420 described above. A plurality of through insulating vias (TIVs) 520 may surround the bridge die 510 and are laterally covered by the second insulating encapsulation 420B. In some embodiments, the bridge die 510 includes the semiconductor substrate 212, the interconnect structure 214 overlying the semiconductor substrate 212, and the TSVs 220 penetrating through the semiconductor substrate 212 to electrically couple the IC dies 410 to conductive joints 515. For example, the conductive joints 515 connect the TSVs 220 of the bridge die 510 to the package substrate 450 and also connect the TIVs 520 to the package substrate 450.

The semiconductor structure 10D may include various dies such as memory dies 410M disposed on the package substrate 450 and next to the IC dies 410, where the memory dies 410M may be electrically coupled to the IC dies 410 at least through the package substrate 450. In some embodiments, the semiconductor structure 500 includes various passive devices 410P disposed on the package substrate 450 and next to the memory dies 410M. The passive device 410P may be optionally disposed on the package substrate 450 next to the external terminals 454. In some embodiments, the semiconductor structure 500 includes a lid 530 disposed on the package substrate 450 and attached to the IC dies 410 and the memory dies 410M. For example, the lid 530 may be coupled to the package substrate 450 through the adhesive layer 530A. The lid 530 may be thermally coupled to the IC dies 410 and the memory dies 410M through thermal interface material layers 530B. In some embodiments, the adhesive layer 530A and the thermal interface material layers 530B are of the same (or similar) material(s). It should be noted that the semiconductor structure 500 illustrated herein is an example, and other embodiments may use fewer or additional elements.

Accordingly, in some embodiments, the present disclosure relates to a method for forming a through substrate via (e.g., a through silicon via) having a better electrical performance and/or yield.

In accordance with some embodiments of the present disclosure, the present disclosure relates to a method, which includes forming a patterned mask layer having an opening disposed on a first surface of a substrate; performing a cyclic etching and deposition processes from the first surface to form a recess corresponding to the opening and a liner layer disposed thereon; performing a first removal process to remove the liner layer for exposing a portion of the substrate in the recess; and performing a trimming process to remove the portion of the substrate in the recess. In an embodiment, the first removal process is performed to remove the liner layer for exposing a lateral undercut protrusion in the recess; and the trimming process is performed to remove the lateral undercut protrusion. In an embodiment, a vertical distance between the first surface and the lateral undercut protrusion is less than or approximately equal to 1 μm. In an embodiment, the etching process is performed by introducing a first gas; the deposition process is performed by introducing a second gas; and the trimming process is performed by introducing the first gas and the second gas. In an embodiment, the trimming process is performed by introducing SF₆ and fluorocarbon. In an embodiment, wherein the trimming process is performed by an apparatus the same as for performing the etching and/or deposition processes. In an embodiment, the method further includes performing a second removal process to remove the patterned mask layer after performing a trimming process. In an embodiment, the method further includes forming an insulating layer at least in the recess after performing the trimming process; forming a conductive layer at least in the recess and disposed on the insulating layer; and performing a third removal process to remove a portion of the substrate to expose a portion of the conductive layer.

In accordance with some embodiments of the present disclosure, the present disclosure relates to a method, which includes performing a cyclic etching and deposition processes to a first surface of a substrate for forming a recess; and performing a trimming process to the substrate having the recess, wherein: before performing the trimming process, a first included angle is formed between the first surface and a portion of a wall surface of the recess connecting thereto; after performing the trimming process, a second included angle is formed between the first surface and a portion of the wall surface of the recess connecting thereto; and the second included angle is closer to 90 degrees than the first included angle. In an embodiment, the etching process is performed by introducing a first gas; the deposition process is performed by introducing a second gas; and the trimming process is performed by introducing the first gas and the second gas. In an embodiment, the trimming process is performed by introducing SF₆ and fluorocarbon. In an embodiment, the trimming process is performed by an apparatus the same as for performing the etching and/or deposition processes. In an embodiment, the wall surface of the recess is in a plurality of scalloped shape. In an embodiment, an aspect ratio of the recess is in a range of approximately 4:1 to approximately 30:1. In an embodiment, the method further includes forming an insulating layer at least in the recess after performing the trimming process; forming a conductive layer at least in the recess and disposed on the insulating layer; and performing a removal process to remove a portion of the substrate to expose a portion of the conductive layer.

In accordance with some embodiments of the present disclosure, the present disclosure relates to a method, which includes providing a substrate; forming a recess on a first surface of the substrate; and forming a structure filling in the recess and in contact with the substrate to form a corresponding interface, wherein: an included angle between the first surface and the interface is larger than or approximately equal to 65 degrees. In an embodiment, the included angle is further larger than or approximately equal to 70 degrees. In an embodiment, the method further includes performing a trimming process to the recess before forming the structure. In an embodiment, the trimming process is performed by introducing SF₆ and fluorocarbon. In an embodiment, the structure comprises a conductive material, and the method further includes performing a removal process to remove a portion of the substrate and a portion of the structure for forming a through substrate via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a patterned mask layer having an opening disposed on a first surface of a substrate;
performing a cyclic etching and deposition processes from the first surface to form a recess corresponding to the opening and a liner layer disposed thereon;
performing a first removal process to remove the liner layer for exposing a portion of the substrate in the recess; and
performing a trimming process to remove the portion of the substrate in the recess.

2. The method of claim 1, wherein:
the first removal process is performed to remove the liner layer for exposing a lateral undercut protrusion in the recess; and
the trimming process is performed to remove the lateral undercut protrusion.

3. The method of claim 2, wherein a vertical distance between the first surface and the lateral undercut protrusion is less than or approximately equal to 1 μm.

4. The method of claim 1, wherein:
the etching process is performed by introducing a first gas;
the deposition process is performed by introducing a second gas; and
the trimming process is performed by introducing the first gas and the second gas.

5. The method of claim 1, wherein the trimming process is performed by introducing SF₆ and fluorocarbon.

6. The method of claim 1, wherein the trimming process is performed by an apparatus the same as for performing the etching and/or deposition processes.

7. The method of claim 1, further comprising:
performing a second removal process to remove the patterned mask layer after performing a trimming process.

8. The method of claim 1, further comprising:
forming an insulating layer at least in the recess after performing the trimming process;
forming a conductive layer at least in the recess and disposed on the insulating layer; and
performing a third removal process to remove a portion of the substrate to expose a portion of the conductive layer.

9. A method, comprising:
performing a cyclic etching and deposition processes to a first surface of a substrate for forming a recess; and
performing a trimming process to the substrate having the recess, wherein:
before performing the trimming process, a first included angle is formed between the first surface and a portion of a wall surface of the recess connecting thereto;
after performing the trimming process, a second included angle is formed between the first surface and a portion of the wall surface of the recess connecting thereto; and
the second included angle is closer to 90 degrees than the first included angle.

10. The method of claim 9, wherein:
the etching process is performed by introducing a first gas;
the deposition process is performed by introducing a second gas; and
the trimming process is performed by introducing the first gas and the second gas.

11. The method of claim 9, wherein the trimming process is performed by introducing SF₆ and fluorocarbon.

12. The method of claim 9, wherein the trimming process is performed by an apparatus the same as for performing the etching and/or deposition processes.

13. The method of claim 9, wherein the wall surface of the recess is in a plurality of scalloped shape.

14. The method of claim 9, wherein an aspect ratio of the recess is in a range of approximately 4:1 to approximately 30:1.

15. The method of claim 9, further comprising:
forming an insulating layer at least in the recess after performing the trimming process;
forming a conductive layer at least in the recess and disposed on the insulating layer; and
performing a removal process to remove a portion of the substrate to expose a portion of the conductive layer.

16. A method, comprising:
providing a substrate;
forming a recess on a first surface of the substrate; and
forming a structure filling in the recess and in contact with the substrate to form a corresponding interface, wherein:
an included angle between the first surface and the interface is larger than or approximately equal to 65 degrees.

17. The method of claim 16, wherein the included angle is further larger than or approximately equal to 70 degrees.

18. The method of claim 16, further comprising:
performing a trimming process to the recess before forming the structure.

19. The method of claim 18, the trimming process is performed by introducing SF₆ and fluorocarbon.

20. The method of claim 16, wherein the structure comprises a conductive material, and the method further comprising:
performing a removal process to remove a portion of the substrate and a portion of the structure for forming a through substrate via.
